(19) United States
(12) Patent Application Publication
(10) Pub. No.: US 2013/0054166 A1
(43) Pub. Date: Feb. 28, 2013

(54) INFORMATION PROCESSING APPARATUS, INFORMATION PROCESSING METHOD, AND PROGRAM

(71) Applicants: Hirotaka Suzuki, Kanagawa (JP); Kenta Kawamoto, Tokyo (JP)

(72) Inventors: Hirotaka Suzuki, Kanagawa (JP); Kenta Kawamoto, Tokyo (JP)

(73) Assignee: Sony Corporation, Tokyo (JP)

(21) Appl. No.: 13/571,719

(22) Filed: Aug. 10, 2012

(30) Foreign Application Priority Data
Aug. 23, 2011 (JP) 2011-181525

(51) Int. Cl. G06F 19/00; G01R 21/00

(52) U.S. Cl. 702/62; 702/61

(57) ABSTRACT

In some embodiments, a system comprising a first and a second computing device is disclosed. The first computing device, comprising at least one processor, is configured to obtain, from a second computing device, data related to power consumption by at least a first electrical device located in a first region of a plurality of regions, and classify the first region, based at least in part on the obtained data, into a first group of regions of a plurality of groups of regions. The second computing device, comprising at least another processor, is configured to transmit, to the first computing device, the data related to power consumption by at least the first electrical device, and receive, from the first computing device information related to power consumption by a second electrical device located in a second region, wherein the second region is in the first group of regions.

### FIELD

Some embodiments described in the present application relate to an information processing apparatus, an information processing method, and a program, and, in particular, to an information processing apparatus, an information processing method, and a program which provide a mechanism which enables users to actively participate in reduction of power consumption.

### BACKGROUND

A system has been proposed which monitors the usage states (ON and OFF states) of a plurality of electrical appliances connected to the downstream side of a distribution board in such a way as to measure the current waveform of one part of the distribution board, which is the fundamental power supply, using a clamp ammeter or the like in each household (for example, see JP-A-2008-039492 and “Nonintrusive Appliance Load Monitoring System—Discrete Operating Conditions and Integer Programming-”, 42nd SICE (Society of Instrument and Control Engineers) discrete event system study group, pp. 33-38, Dec. 20, 2008, Osaka University).

The object of visualization of the usage state of each of the electrical appliances in the household is the reduction of power consumption or the control of the peak power value through an understanding of the power usage states of users. In addition, the reduction in CO₂ emissions, obtained through user's active participation in power saving (eco-activity), can be expected as a secondary effect. In the 2009 United Nations Climate Change Conference, Japan declared to aim for a reduction in CO₂ emissions of 25% compared to 1990 by the year 2020.

In the related art, as a method of prompting users in a household or an office to save power, the total amount of power is merely displayed using a numerical number or a graph, or virtual display is performed in such a way that the peak of a mountain is selected as a goal (target) and the mountain is climbed according to the accumulation of power saving.

### SUMMARY

However, since it is difficult to realize the participation in the reduction of power consumption (eco-activity) using the method in the related art, users are tired of power saving, so that there are many cases in which the desire to save power does not continue. In addition, since information indicative of a detailed way of using household electrical appliances in order to achieve power saving is not provided to the users, it is difficult to effectively reduce power consumption even though the users have a higher awareness for saving power.

It is therefore desirable to provide a mechanism which enables users to actively participate in reduction of power consumption.

An information processing apparatus according to one embodiment of the present disclosure includes an acquisition unit which obtains data indicative of the amount of power consumption of one or more electrical appliances in each of a plurality of regions; a classification unit which classifies the plurality of regions into a predetermined number of groups based on the obtained data; and an information provision unit which, for each group obtained through classification, provides a service for exchanging information about the amount of power consumption between users who use the electrical appliances of each of the regions which belong to the group.

An information processing method according to one embodiment of the present disclosure includes obtaining data indicative of the amount of power consumption of one or more electrical appliances in each of a plurality of regions; classifying the plurality of regions into a predetermined number of groups based on the obtained data; and providing, for each group obtained through classification, a service for exchanging information about the amount of power consumption between users who use the electrical appliances of each of the regions which belong to the group.

A program according to one embodiment of the present disclosure causes a computer to perform a process including obtaining data indicative of the amount of power consumption of one or more electrical appliances in each of a plurality of regions; classifying the plurality of regions into a predetermined number of groups based on the obtained data; and providing, for each group obtained through classification, a service for exchanging information about the amount of power consumption between users who use the electrical appliances of each of the regions which belong to the group.

According to the embodiments of the present disclosure, data indicative of the amount of power consumption of one or more electrical appliances in each of a plurality of regions is obtained, the plurality of regions are classified into a predetermined number of groups based on the obtained data, and, for each group obtained through classification, information about the amount of power consumption is exchanged between users who use the electrical appliances of each of the regions which belong to the group.

In some embodiments, a computing device comprising at least one processor is disclosed. The at least one processor is configured to obtain data related to power consumption by at least a first electrical device located in a first region of a plurality of regions, and classify the first region, based at least in part on the obtained data, into a first group of regions of a plurality of groups of regions.

In some embodiments, a method is disclosed. The method comprises obtaining data related to power consumption by at least a first electrical device located in a first region of a plurality of regions, and classifying the first region, based at least in part on the obtained data, into a first group of regions of a plurality of groups of regions.

In some embodiments, another computing device comprising at least one processor is disclosed. The at least one processor is configured to transmit, to at least another computing device, data related to power consumption by at least a first electrical device located in a first region of a plurality of regions; and receive, from the other computing device, information related to power consumption by at least a second electrical device located in a second region different from the first region, wherein the first and the second regions are each in a first group of regions of a plurality of groups of regions.

In some embodiments, a system comprising a first and a second computing device is disclosed. The first computing device, comprising at least one processor, is configured to obtain, from a second computing device, data related to power consumption by at least a first electrical device located in a first region of a plurality of regions, and classify the first region, based at least in part on the obtained data, into a first group of regions of a plurality of groups of regions. The second computing device, comprising at least another processor, is configured to transmit, to the first computing device, the data related to power consumption by at least the first electrical device, and receive, from the first computing device information related to power consumption by a second electrical device located in a second region, wherein the second region is in the first group of regions.

The program can be provided by recording the program in a recording medium.

The information processing apparatus may be an independent apparatus or may be an internal block which constitutes a single apparatus.

According to some embodiments of the present disclosure, it is possible to provide a mechanism which enables users to actively participate in reduction of power consumption.

The foregoing is a non-limiting summary of the invention, which is defined by the attached claims.

### BRIEF DESCRIPTION OF THE DRAWINGS

FIG. 1 is a view illustrating a configuration example of an information processing system to which an embodiment of the present disclosure is applied;

FIG. 2 is a view illustrating the outline of a data process performed by a server apparatus;

FIG. 3 is a block diagram illustrating the functions of a client apparatus and the server apparatus;

FIG. 4 is a view illustrating an example of power profiles;

FIG. 5 is a view illustrating an example of data processing performed by a data processing unit;

FIG. 6 is a view illustrating a process performed by a group classification unit;

FIG. 7 is a flowchart illustrating a process performed by the client apparatus;

FIG. 8 is a flowchart illustrating a process performed by the server apparatus;

FIG. 9 is a view illustrating an example of a method of obtaining the power profile of each user in a household;

FIG. 10 is a view illustrating an example of a method of obtaining the power profile of each user at home; and

FIG. 11 is a block diagram illustrating a configuration example of a computer to which the embodiment of the present disclosure is applied.

### DETAILED DESCRIPTION

### Configuration Example of Information Processing System

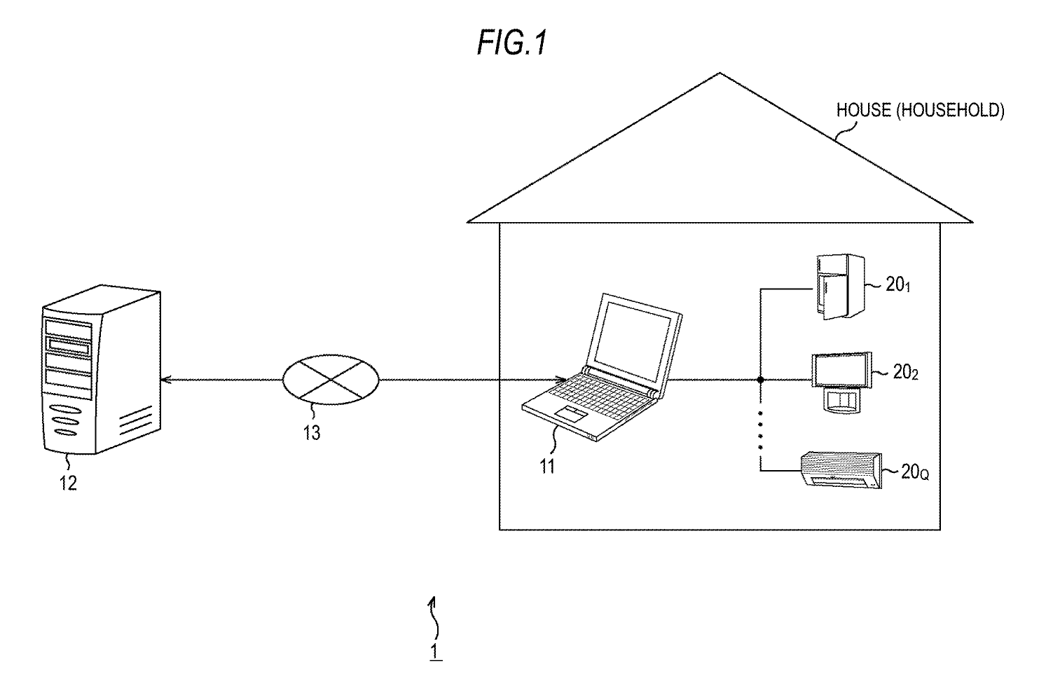

FIG. 1 is a view illustrating a configuration example of an information processing system to which an embodiment of the present disclosure is applied.

An information processing system 1 shown in FIG. 1 includes a client apparatus 11 placed in each of N(N>2) households, and a server apparatus 12 connected to the client apparatus 11 over a network 13. Meanwhile, in FIG. 1, only the client apparatus 11 of a single household is shown. The network 13 used to connect the client apparatus 11 with the server apparatus 12 is, for example, a wired or wireless network which includes a LAN (Local Area Network), a WAN (Wide Area Network), the Internet, or the like.

The client apparatus 11 obtains the time-series profiles of power consumption (hereinafter, referred to as power profile) for the respective electrical appliances 20 which are placed in a house (household), and then transmits the obtained power profile to the server apparatus 12. The electrical appliances 20 include, for example, a refrigerator 20₁, a television receiver (hereinafter, referred to as a TV) 20₂, an air conditioner 20_{Q}, and the like, as shown in FIG. 1.

Meanwhile, the client apparatus 11 can transmit the power profile for each user, such as the father, the mother, a child or the like who resides in the household, to the server apparatus 12 as described later. However, an example in which a power profile for each electrical appliance 20 is transmitted will be described as a basic embodiment below.

The server apparatus 12 obtains the power profiles of the electrical appliances 20 of each of the households from the client apparatus 11 of each of the households. Thereafter, the server apparatus 12 analyzes the power profiles obtained from each of the households, and transmits information about the amount of power consumption of the household which corresponds to the client apparatus 11 to the client apparatus 11 as the result of the analysis. The information about the amount of power consumption includes, for example, information about the ranking of the amount of power consumption or the amount of power saving of a household from among the whole households from which the server apparatus 12 collects data, knowledge information used as know-how for saving power, information which is helpful to improve the motivation for power saving behavior, and the like.

The client apparatus 11 receives the result of the analysis, obtained in such a way that the server apparatus 12 collects the power profiles from each of the households and then and analyzes the collected power profiles, from the server apparatus 12, and then displays the result of the analysis on a display which functions as a display unit.

### [Outline of Data Processing Performed by Server Apparatus 12]

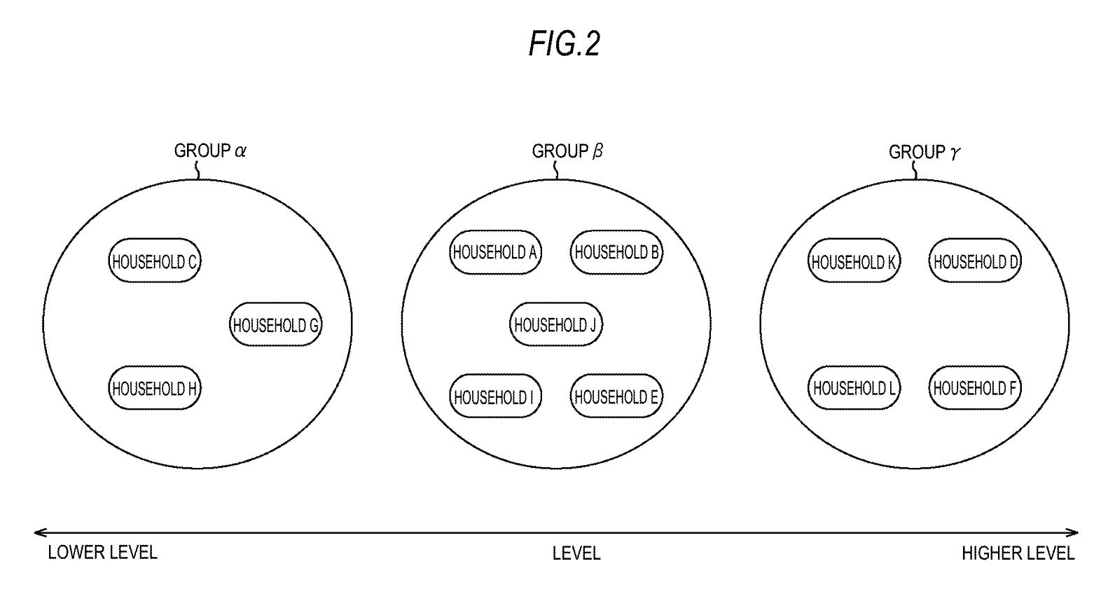

The outline of data processing, performed by the server apparatus 12 using the power profiles aggregated from each of the households, will be described with reference to FIG. 2.

The server apparatus 12 classifies the households into a predetermined number (K) of groups (clusters) based on the similarity of the power profiles of the electrical appliances 20 of each of the households, the power profiles being received from the client apparatus 11 of each of the households. FIG. 2 shows an example in which 12 households (N=12), ranging from a household A to a household L, are classified into 3 groups (K=3), that is, a group α, a group β, and a group γ.

In addition, the server apparatus 12 determines the level (rank) of each of the groups, obtained through the classification, based on the degree of energy-saving of each of the groups, for example, the amount of power saving. In the example of FIG. 2, the level of the group γ is determined as the highest level, and then the level is determined in order of the group β and the group α.

A user of a household who transmitted the power profiles to the server apparatus 12 can obtain information indicative of a group to which the household of the user belongs from among K groups based on a power saving behavior level, information indicative of the order of the power saving behavior level of the group to which the user household belongs, information indicative of the difference from a high level group, and the like as the result of the analysis from the server apparatus 12, and can be aware of the pieces of information. Therefore, it is possible to arouse the desire of the user to raise the level to a higher level, and to improve the motivation of the power saving behavior of the user.

The server apparatus 12 forms a community for each group in which households in the group can mutually exchange opinions or information, and provides the community to the client apparatuses 11 of the users. That is, the server apparatus 12 sets K communities, and enables the client apparatuses 11 of the respective households which belong to the same group to access the same community. The community is a communication tool and/or an information-sharing tool which includes, for example, the community of SNS (Social Networking Service/Site), a blog, a bulletin board, Facebook, Twitter, or the like at which everyone can write and publish opinions. Therefore, the server apparatus 12 has the function of a service server which provides a way for users to share information with one another by using a communication tool and/or an information-sharing service.

The server apparatus 12 determines the rank of each of the households in the same group based on the degree of energy saving (the amount of power saving), and gives points to high-ranking households. In addition, the titles of an “Eco-Sommelier”, an “Eco-Meister” and the like, qualification, or position is granted to the user of a household which is continuously highly ranked, and points are given to such a title or the like. Therefore, the households in the same group can compete for the degree of energy saving.

In addition, when the user sends information, such as power saving know-how or the like which is helpful to save power, in the community, the server apparatus 12 gives points to the household of the user. The importance of a user, to which a title such as “Eco-Sommelier”, “Eco-Meister or the like is given, is naturally increased in a community when sending information, and the user attracts other users' attention in the community. For example, if an idea, such as “How to save more power?”, is sent from an Eco-sommelier, the idea is effectively spread to other users of the same group, so that energy saving is accelerated in the whole group.

Therefore, the user can accumulate points as the user performs power saving behavior. In addition, the user can accumulate points as the user provides information which is helpful to save power. Based on such a mechanism, it is possible to accelerate the power saving behavior in the entire group (community).

The given points has worth which becomes practical benefits for the user, such as virtual money which can be used for fare-paying service in the community, government eco points, points which can be turned into money or can be used to purchase products at predetermined stores, or the like.

Meanwhile, the points given to the above-described title, such as “Eco-Meister” or the like, or points corresponding to sending information within the community may be given in units of a user instead of units of a household. In this case, it is preferable that the power profile be aggregated in units of a user.

Since the server apparatus 12 performs clustering based on the similarity between the power profiles, a group (community) is formed by households having similar power profiles. Rather than the competition between the households having total different power profiles, the competition between the households having similar power profiles increases sympathetic awareness or competition awareness, so that it is easy to increase the affinity in the community. In addition, it is easy to share information, such as power saving knowledge or the like, between the households having similar power profiles. Therefore, it is possible to improve the motivation of the power saving behavior of users by performing competition within the clustered group.

### [Block Diagram Illustrating Functions of Information Processing Apparatus and Server Apparatus]

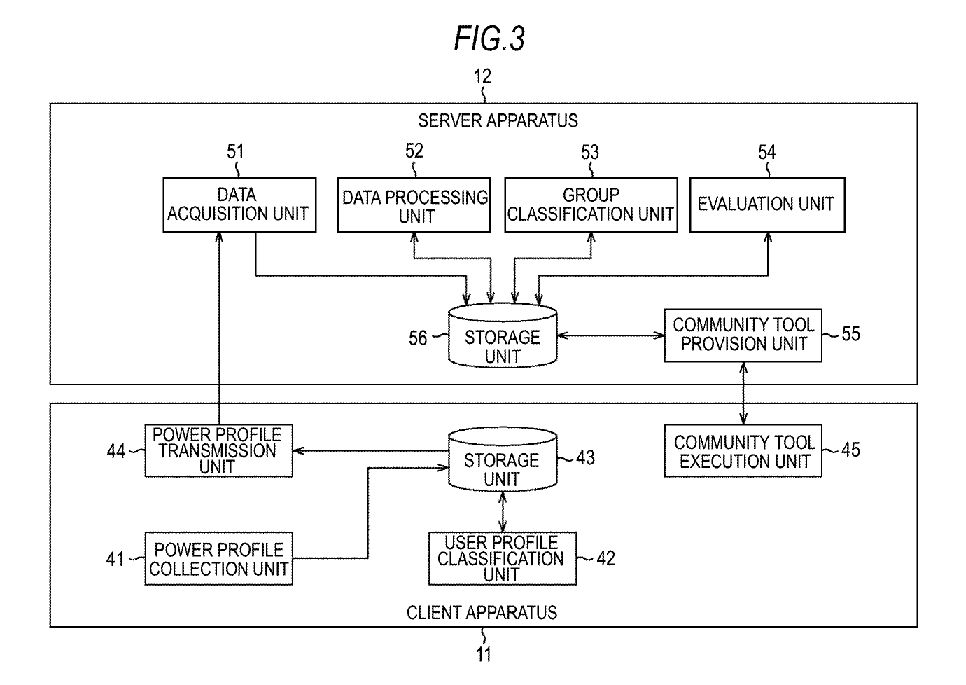

FIG. 3 is a block diagram illustrating the functions of the client apparatus 11 and the server apparatus 12, which are used to implement the functions described with reference to FIG. 2.

The client apparatus 11 includes a power profile collection unit 41, a user profile classification unit 42, a storage unit 43, a power profile transmission unit 44, and a community tool execution unit 45.

The power profile collection unit 41 obtains the power profiles of the plurality of electrical appliances 20 placed in the household, and stores the obtained power profiles in the storage unit 43. For example, the power profile collection unit 41 obtains the power profile of each of the electrical appliances 20 by communicating in wired or wireless manner with a power monitoring apparatus which is embedded in each of the electrical appliances 20, a clamp meter which clamps the power code of each of the electrical appliances 20 and measures the consumption current, or the like. The power profile is a time-series data of used power or consumption current sampled at predetermined sampling intervals.

Meanwhile, as described in “BACKGROUND”, there is a power consumption estimation technology which measures the total consumption current of one part of a distribution board, which becomes the fundamental power of the power supply of a household, using a clamp meter, and estimates the power on/off state of each of the connected electrical appliances 20 in the household and the power consumption based on a result of the measurement. The power profile collection unit 41 may obtain only total consumption current of the fundamental power using such a power consumption estimation technology, perform separate estimation on the profile of each of the electrical appliances 20 in the household based on the obtained data, and then store the result of estimation in the storage unit 43.

The user profile classification unit 42 performs classification on the power profile data of each of the electrical appliances 20, which is collected by the power profile collection unit 41 and stored in the storage unit 43, for each user in the household, and then stores the result of classification in the storage unit 43. The user profile classification unit 42 is necessary when the power profile for each user is transmitted to the server apparatus 12. In the case where it is sufficient to transmit only power profiles for the respective electrical appliances 20, the user profile classification unit 42 can be omitted.

Meanwhile, in the present embodiment, the way of obtaining the power profile for each electrical appliance 20, the power profile for each user of each of the electrical appliances 20, the power profile for each user, or the like is not a problem, and it is sufficient to obtain a necessary power profile in some way. An example of a method of performing classification on the power profiles of the electrical appliances 20 for each user will be described later.

The storage unit 43 stores the power profiles of the respective electrical appliances 20, which are supplied from the power profile collection unit 41 and the user profile classification unit 42. In addition, the storage unit 43 stores the power profiles of the respective electrical appliances 20 for each user and the power profile for each user as necessary. That is, the storage unit 43 stores power profiles which need to be transmitted to the server apparatus 12.

The power profile transmission unit 44 transmits the power profiles accumulated in the storage unit 43 to the server apparatus 12 over the network 13 (see FIG. 1). For example, at a point of time that the power profiles are accumulated for a predetermined period, such as a day, a week, or the like, the power profile transmission unit 44 accesses the server apparatus 12 and then transmits the accumulated power profiles. In addition, the power profile transmission unit 44 may transmit the power profiles stored in the storage unit 43 to the server apparatus 12 when the transmission of the power profiles is indicated by a user using a manipulation unit (not shown).

The community tool execution unit 45 accesses the server apparatus 12 based on the manipulation of the user, obtains information supplied by the server apparatus 12, and then displays the information. In detail, ranking information in units of a household or in units of a user or information in a community to which the household corresponding to the client apparatus 11 belongs is received and then displayed. The information is described with reference to FIG. 2.

The server apparatus 12 includes a data acquisition unit 51, a data processing unit 52, a group classification unit 53, an evaluation unit 54, a community tool provision unit 55, and a storage unit 56.

The data acquisition unit 51 receives the power profiles which are transmitted from the client apparatus 11 of each of the households over the network 13, and stores the power profiles in the storage unit 56. Meanwhile, a household ID (Identification) used to identify each of the households and an equipment ID used to identity each of the electrical appliances 20 are added to each of the power profiles transmitted from the client apparatus 11. In addition, when the comparison is performed on the power consumption for each user of each of the households, a user ID used to identify each of the users in the household is added. Meanwhile, the user ID may be an ID used to identify the user itself in the household, and may be an ID used to identify the type of a user, such as an adult man, an adult woman, a child, a man in his thirties, a woman in her teens, or the like, when classification is performed using a type which is considered that the patterns of the power profiles are similar.

The data processing unit 52 processes the power profiles of the respective electrical appliances 20 of each of the households, which are stored in the storage unit 56, as data which is suitable to perform classification using the group classification unit 53, and then stores the processed data in the storage unit 56.

The group classification unit 53 classifies the households into K groups (clusters) based on the power profiles of the respective electrical appliances 20 of each of the households, which are stored in the storage unit 56 after the data processing is performed. The result of classification performed by the group classification unit 53 is stored in the storage unit 56.

The evaluation unit 54 determines rank (ranking) in units of a group or in units of a household.

In detail, the evaluation unit 54 calculates the average of the total amount of power consumption of the households which belong to a group with respect to each of the groups obtained through classification performed by the group classification unit 53, and determines the rank of the group in order of group which has the smaller average of the calculated total amount of power consumption. That is, as a group the total amount of power consumption of which is small, the rank (level) thereof becomes high.

In addition, the evaluation unit 54 determines the ranks of each of the households in the group. The rank of each of the households is determined based on the amount of reduction of power consumption. For example, the evaluation unit 54 calculates the amount of reduction based on the difference between the amount of power consumption for a month of a current month and the amount of power consumption for a month of the last month, and determines the rank of each of the households such that a household having a large amount of reduction is ranked high. Meanwhile, the evaluation unit 54 may determine the rank of each of the households using the difference between the amount of power consumption for a month of the current month and the amount of power consumption of a year ago current month as the amount of reduction, and may determine the rank of each of the households using the total amount of power of the household as the same when a rank is determined between groups. That is, an index used for determining rank can be arbitrarily set.

The community tool provision unit 55 performs a service for supplying a community to the household of the user of the client apparatus 11 for each group obtained through classification. That is, the community tool provision unit 55 provides information, provided in a community corresponding to a group to which the household of the client apparatus 11 belongs, to the accessed client apparatus 11. The user can open information of the user, which is helpful to save power, in the community to which the user belongs or can browse information opened by another user in the same community using the community tool execution unit 45 of the client apparatus 11.

In addition, the community tool provision unit 55 provides ranking information determined by the evaluation unit 54 in units of a group or in units of a household to the community tool execution unit 45 of the client apparatus 11 in addition to providing the exchange of information within the community.

Therefore, the user can be aware of information about a group, such as the rank of each group, the difference in the amount of power consumption between a group to which the user (the household of the user) belongs and a group at the next superior level via the community tool execution unit 45 of the client apparatus 11.

In addition, the user can be aware of information within a group, such as the amount of power consumption of the household of the user, the amount of power consumption of each of the households in the same group to which the user belongs, power saving know-how disclosed in the community, the points (of the household) of the user, which are given depending on power saving behavior, or the like. Meanwhile, the amount of power consumption, the ranking (rank), or the like is graphically displayed using a bar graph, a circle graph, a polygonal line graph, or the like in order to easily compare with data.

### [Example of Process Performed on Power Profile]

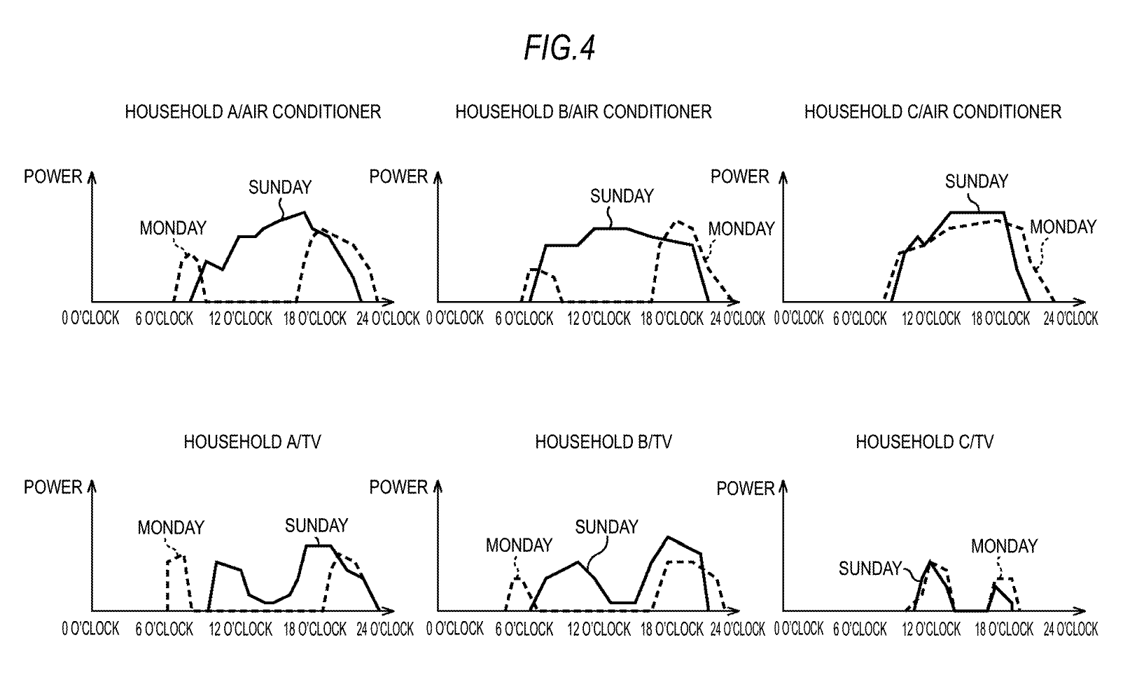

Next, processes performed by the data processing unit 52 and the group classification unit 53 will be described with reference to FIGS. 4 to 6.

FIG. 4 illustrates an example of power profiles which are obtained in each of the households including a household A, a household B, a the household C, and transmitted to the server apparatus 12, that is, the power profiles of an air conditioner 20_{Q} and a TV 20₂ which function as the electrical appliances 20.

The three upper graphs from among the six graphs shown in FIG. 4 illustrate the power profiles of the air conditioners 20_{Q} of the household A, the household B, and the household C, and the three lower graphs illustrate the power profiles of the TVs 20₂ of the household A, the household B, and the household C.

In addition, in FIG. 4, when the two upper and lower graphs are viewed as a set, the power profiles of the air conditioner 20_{Q} and the TV 20₂ of each of the households are shown in order of the household A, the household B, and the household C in order from the left to right direction.

Further, two types of power profile, that is, a solid line and a dotted line, are shown in each of the six graphs. The solid line indicates a power profile measured on Sunday, and the dotted line indicates a power profile measured on Monday.

From among the six graphs shown in FIG. 4, comparison is performed on the power profiles of the upper air conditioners 20_{Q} of the respective households. While the household A and the household B do not use power during daylight (before and after 12 O'clock) on Monday which is a weekday, the household C uses the same power on Monday as on Sunday. Therefore, it can be seen that the household A and the household B have similar life patterns, for example, users are not home during the daylight of a weekday because of couples working or the like, and have a resemblance to each other. The group classification unit 53 quantitatively performs classification on such a power profile.

First, the data processing unit 52 processes the power profiles of the respective households shown in FIG. 4 to data which is suitable for performing classification by the group classification unit 53.

For example, the data processing unit 52 performs a process such that the amounts of power consumption of the electrical appliances 20 of the respective households are integrated over two hours and then becomes one piece of data for two hours. Thereafter, the data processing unit 52 generates a feature quantity vector which indicates the feature quantity of the power profile of each of the households by arranging the integrated values of the amounts of power consumption of the respective electrical appliances 20 of the respective households per every two hours in a predetermined order of the electrical appliances 20. Meanwhile, with respect to a single electrical appliance 20, the integrated values of the amounts of power consumption per every two hours is arranged in order of determined certain days.

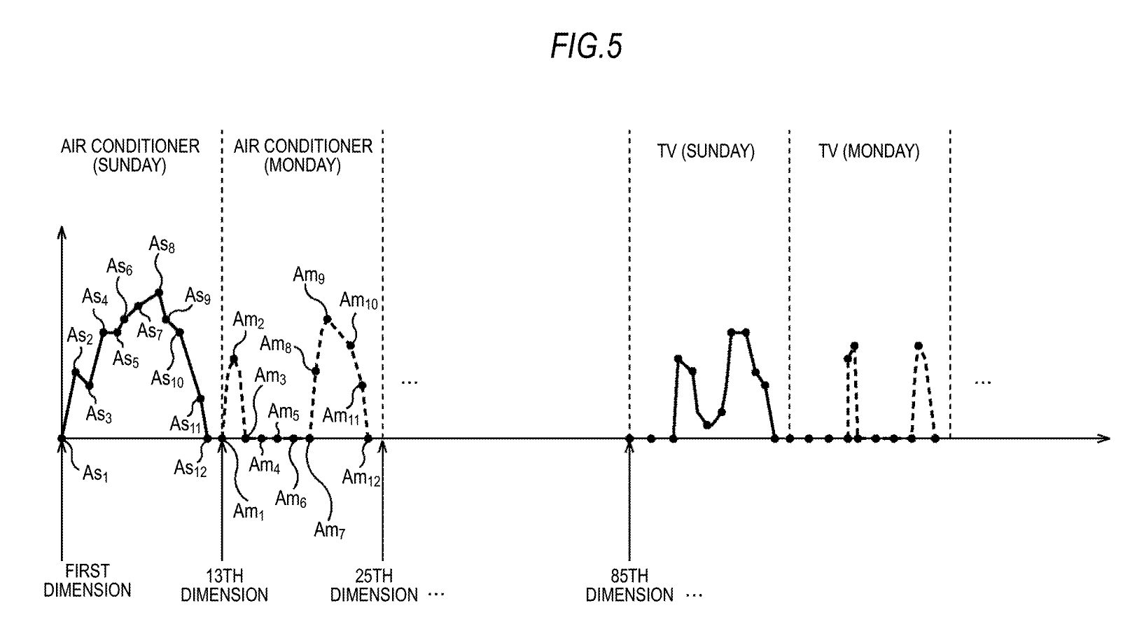

For example, a feature quantity vector x_{A} indicative of the feature quantity of the power profile of the household A can be expressed as the following Equation (1). The feature quantity vector x_{A} is illustrated as in FIG. 5.

$${x}_{A} = ( \begin{matrix}{As}_{1} \\ {As}_{2} \\ ⋮ \\ {As}_{12} \\ {Am}_{1} \\ {Am}_{2} \\ ⋮ \\ {Am}_{12} \\ ⋮ \\ {TVs}_{1} \\ {TVs}_{2} \\ ⋮\end{matrix} ) \qquad ( 1 )$$

As₁, As₂, As₃, As₄, As₅, . . . , and As₁₂ in Equation (1) and FIG. 5 indicate the integrated values of the amount of power consumption of the air conditioner 20_{Q} of the household A at 0 to 2 o'clock, 2 to 4 o'clock, 4 to 6 o'clock, 6 to 8 o'clock, 8 to 10 o'clock, . . . , 22 to 24 o'clock on Sunday. In addition, Am₁, Am₂, Am₃, Am₄, Am₅, . . . , Am₁₂ indicate the integrated values of the amount of power consumption of the air conditioner 20_{Q} at 0 to 2 o'clock, 2 to 4 o'clock, 4 to 6 o'clock, 6 to 8 o'clock, 8 to 10 o'clock, . . . , 22 to 24 o'clock on Monday. TVs₁, TVs₂, TVs₃, TVs₄, TVs₅, . . . , TVs₁₂ indicate the integrated values of the amount of power consumption of the TV 20₂ of the household A at 0 to 2 o'clock, 2 to 4 o'clock, 4 to 6 o'clock, 6 to 8 o'clock, 8 to 10 o'clock, . . . , 22 to 24 o'clock on Sunday. Therefore, the number of the dimension of the feature quantity vector of each of the households for a week becomes 12×7×Q (the number of dimension for a day×the number of days×the number of electrical appliances 20).

In the way described above, the feature quantity vector xᵢ of each of the N households i (i=1 to N) is obtained by the data processing unit 52, and then stored in the storage unit 56.

The group classification unit 53 classifies N households 1 to N into K groups (clusters) with a predetermined classification method using the feature quantity vector xᵢ of each of the households i.

For example, the group classification unit 53 uses K-means clustering as the predetermined classification method, and classifies N households 1 to N into K groups. In this case, the group classification unit 53 performs the following steps.

### (Step S1)

The group classification unit 53 randomly allocates any of K clusters 1 to K to the feature quantity vector xᵢ of each of the households i.

### (Step S2)

With respect to each allocated cluster, the group classification unit 53 calculates the center Mⱼ (j=1 to K) of a cluster j. For example, the average of the feature quantity vectors xᵢ of all households i which belong to the cluster is calculated as the center Mⱼ of the cluster.

### (Step S3)

The group classification unit 53 obtains the distance between the feature quantity vector xᵢ of each of the households i and the center Mⱼ of each cluster, and then reallocates the feature quantity vector xᵢ of each of the households i to any of the clusters 1 to K, which has the nearest center.

### (Step S4)

When there is no change in the allocation of the clusters due to the reallocation in step S3, the group classification unit 53 terminates the process. When there is change, steps below the above step (step S2) are repeated using the newly allocated cluster.

In addition, the group classification unit 53 can use a spectral clustering method, characterized by a Normalized-Cuts method, as the classification method used to classify N households into K clusters.

The Normalized-Cuts method will be described in brief. In the Normalized-Cuts method, the dissimilarity between the households are calculated based on the feature quantity vectors xᵢ of the respective households i, and then clustering is performed based on a dissimilarity table obtained by collecting the dissimilarity between all the households.

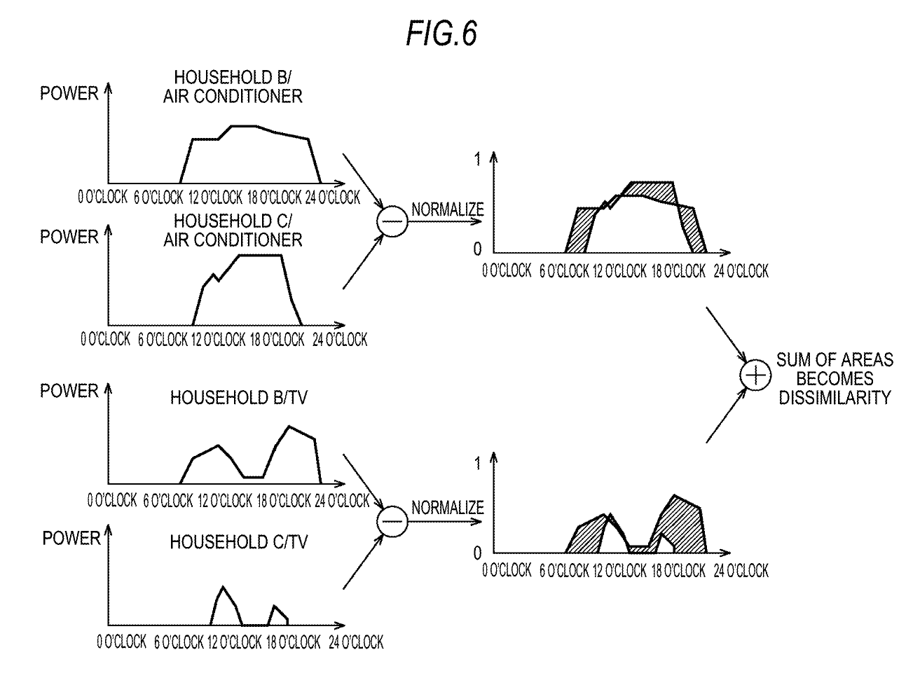

In detail, it is assumed that the number of clusters K is an even number which is equal to or greater than 2, and, first, the dissimilarity between the power profiles of two households is calculated for all the combination of N households. The dissimilarity between the power profiles of a household u (u=1, . . . , N) and a household v (v=1, . . . , N) is expressed as w (u,v). The dissimilarity w (u,v) between the power profiles of the households can be obtained from, for example, the reciprocal number of the Euclidean distance of the above-described feature quantity vectors xᵢ of the respective households i or the integration value of values obtained by normalizing the difference between power profiles of the same electrical appliances 20 of the respective households as shown in FIG. 6.

In addition, the group classification unit 53 divides the N households into two groups, that is, groups GP1 and GP2 by solving the eigen value problem of subsequent Equation (2), calculating an unique vector Z which corresponds to a second-smallest unique value λ, and equally dividing the N-dimensional vector, obtained by multiplying the N-dimensional unique vector z by D^{-1/2}, into two using median.

D^{-1/2}(D−W)D^{-1/2}z=λz (2)

where D is an N×N diagonal matrix in which the diagonal component dᵢᵢ of i-th row and i-th column is expressed using the following Equation, and W is an N×N symmetrical matrix in which the component Wᵢⱼ of i-th row and j-th column is Wᵢⱼ=w(i,j).

$${d}_{ii} = {\sum }_{j}^{ } w ( i , j )$$

Next, the above-described two-division algorithm is applied to each of the groups GP1 and GP2, so that each of the groups GP1 and GP2 is further divided into two. In such a case, the number of households N is replaced with the number of households of the group GP1 or GP2 obtained after division.

Thereafter, a two-division process using the two-division algorithm is recursively repeated until the number of all clusters becomes K, and the process is terminated at a time point that the number of all clusters becomes K.

The detailed explanation of the Normalized-Cuts method is described in, for example, Jianbo Shi and Jitendra Malik (1997): “Normalized Cuts and Image Segmentation”, IEEE Conference on Computer Vision and Pattern Recognition, pp. 731-737.

### [Flow of Process Performed by Client Apparatus 11]

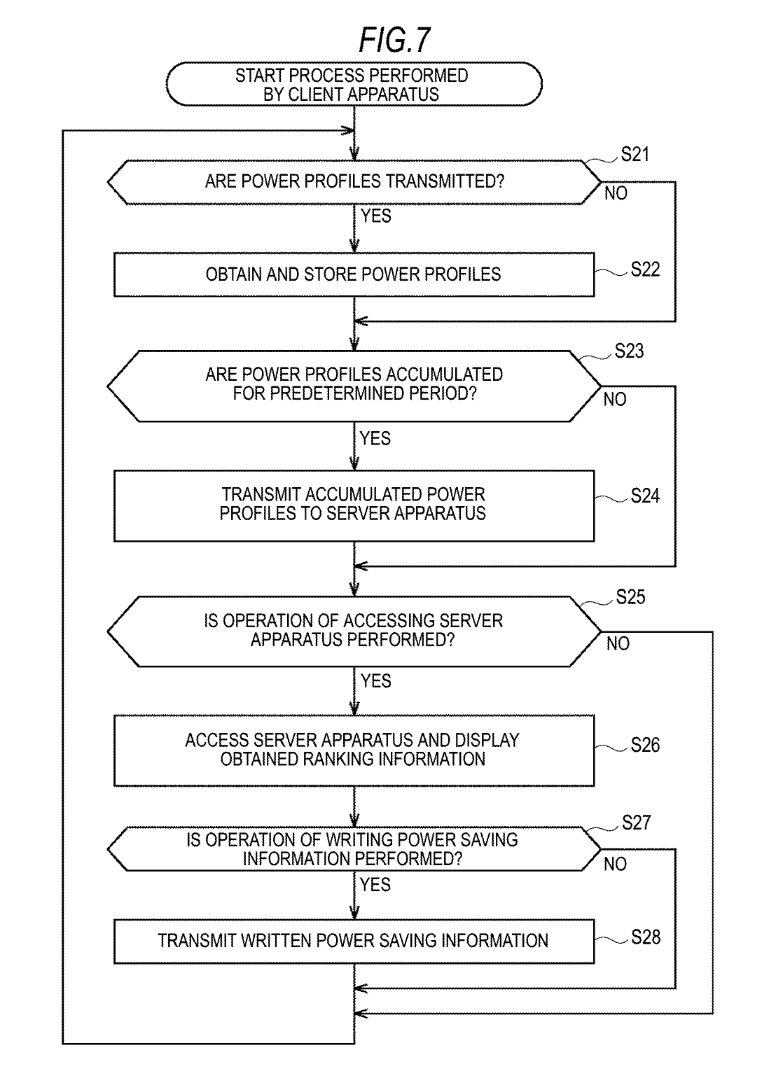

A process performed by the client apparatus 11 will be described with reference to the flowchart of FIG. 7.

First, in step S21, the power profile collection unit 41 determines whether the power profiles of the respective electrical appliances 20, which are placed in the household, are transmitted from the electrical appliance 20, a clamp meter, or the like.

When it is determined that the power profiles of the respective electrical appliances 20 are received in step S21, the process proceeds to step S22, and the power profile collection unit 41 obtains the received power profiles and stores the power profiles in the storage unit 43.

Meanwhile, when it is determined that the power profiles of the respective electrical appliances 20 are not received in step S21, the process in step S22 is skipped.

Next, in step S23, the power profile transmission unit 44 determines whether the power profiles of the respective electrical appliances 20 are accumulated in the storage unit 43 for a predetermined period, for example, a day, a week, or the like.

In step S23, when it is determine that the power profiles of the respective electrical appliances 20 are accumulated for a predetermined period, the process proceeds to step S24, and the power profile transmission unit 44 transmits the power profiles accumulated in the storage unit 43 to the server apparatus 12 over the network 13.

Meanwhile, when it is determine that the power profiles of the respective electrical appliances 20 are not accumulated for a predetermined period in step S23, the process in step S24 is skipped.

Next, in step S25, the community tool execution unit 45 determines whether an operation of accessing the server apparatus 12 is performed by a user.

When it is determined that the operation of accessing the server apparatus 12 is performed by the user in step S25, the process proceeds to step S26, and the community tool execution unit 45 accesses the server apparatus 12 and displays ranking information obtained from the server apparatus 12 on a display. In addition, community information, provided by the server apparatus 12 (for example, bulletin board information or the like), is also displayed in step S26.

Thereafter, in step S27, the community tool execution unit 45 determines whether an operation of writing power saving information to the community provided by the server apparatus 12 is performed. When it is determined that the operation of writing the power saving information is not performed in step S27, subsequent step S28 is skipped.

Meanwhile, when it is determined that the operation of writing the power saving information is performed in step S27, the process proceeds to step S28, and the community tool execution unit 45 transmits the power saving information, written (input) by the user in the community, to the server apparatus 12.

After the process in step S28 is performed or when it is determined that the operation of accessing the server apparatus 12 is not performed in step S25, the process returns to step S21 and the subsequent processes are repeated.

In the client apparatus 11, the following process is performed.

### [Flow of Process Performed by Server Apparatus 12]

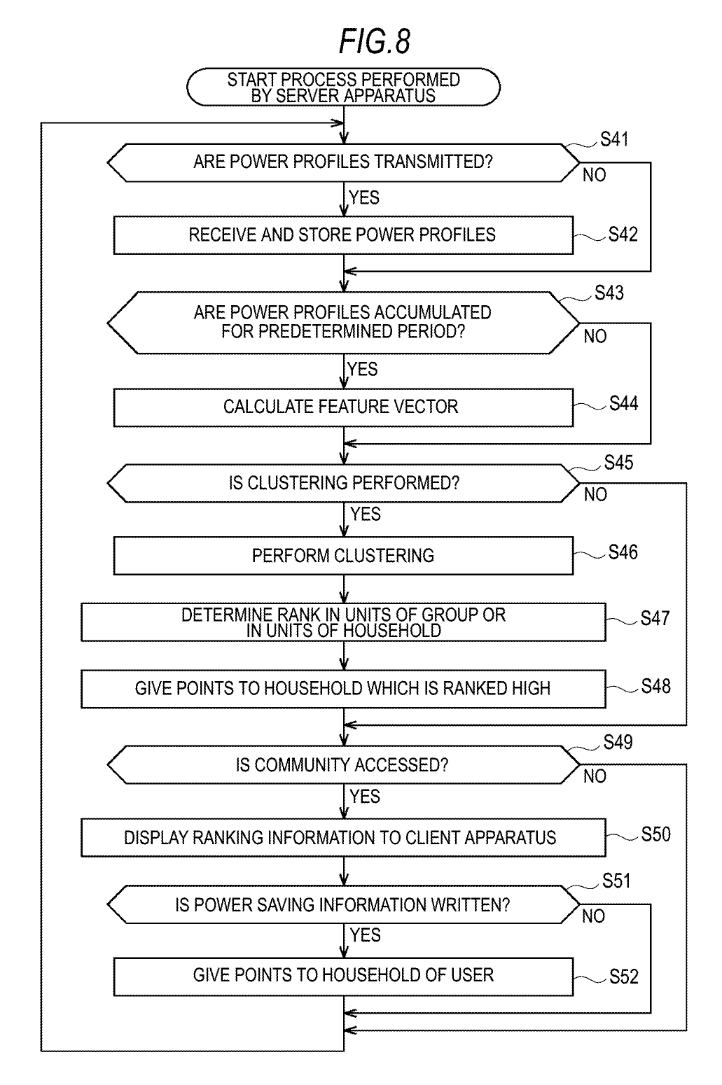

Next, a process performed by the server apparatus 12 in correspondence to the process shown in FIG. 7 will be described. FIG. 8 is a flowchart illustrating the process performed by the server apparatus 12.

First, in step S41, the data acquisition unit 51 determines whether there is access from any of the client apparatus 11 of the respective households and power profiles are received.

In step S41, when it is determined that the power profiles are received, the process proceeds to step S42 and the data acquisition unit 51 receives the received power profiles and stores the power profiles in the storage unit 56.

Meanwhile, when it is determined that the power profiles are not received in step S41, the process in step S42 is skipped.

Subsequently, in step S43, the data processing unit 52 determines whether the power profiles of the respective electrical appliances 20 of each of the households are accumulated in the storage unit 56 for a predetermined period, for example, a day, a week, or the like.

When it is determined that the power profiles are accumulated in the storage unit 56 for a predetermined period in step S43, the process proceeds to step S44, and the data processing unit 52 calculates a feature vector in order to perform clustering.

Meanwhile, when it is determined that the power profiles are not accumulated in the storage unit 56 for a predetermined period in step S43, the process in step S44 is skipped.

Subsequently, the group classification unit 53 determines whether to perform clustering in step S45. When setting is made such that clustering is, for example, periodically (for example, every two months) performed, the group classification unit 53 determines whether to perform clustering depending on whether a predetermined period elapsed from previous clustering. Therefore, the groups of the respective households are periodically sorted, and the interchange of the households between the higher and lower rank groups may occur according to the degree of attainment of energy saving.

When it is determined to perform clustering in step S45, the process proceeds to step S46 and the group classification unit 53 performs clustering using the predetermined classification method, such as K-means clustering, Normalized-Cuts method, or the like.

Subsequently, the evaluation unit 54 determines rank in units of a group or in units of a household in step S47. That is, with respect to each of the groups on which classification is performed by the group classification unit 53, the evaluation unit 54 calculates the average of the total amount of power of each of the households which belong to the group, and then determines rank in order of groups, the average of the calculated total amount of power of which is small. In addition, the evaluation unit 54 calculates the amount of reduction in the amount of power consumption of each of the households for a month, and determines the rank of each of the households in each group in order of a large amount of reduction in the amount of power consumption.

In step S48, the evaluation unit 54 gives points to a household which is ranked high based on the result of ranking in units of a group or in units of a household. The given points are stored in the database of the storage unit 56.

Meanwhile, when it is determined not to perform clustering in step S45, the above-described processes insteps S46 to S48 are skipped.

Subsequently, in step S49, the community tool provision unit 55 determines whether the client apparatus 11, operated by the user, accesses the community provided by the server apparatus 12.

When it is determined that the client apparatus 11 accesses the community in step S49, the process proceeds to step S50, and the community tool provision unit 55 transmits the ranking information, determined based on the power profiles of the respective households, to the client apparatus 11, and then displays the ranking information on the client apparatus 11.

For example, in the client apparatus 11, the history (transfer log) of groups, which includes the recent result of clustering and to which the corresponding household belonged a few times in the past, or the history of the rank (levels) of the groups is displayed as the ranking information. In addition, the transition of the amount of power of the whole household or the transition of the amount of power for each user may be additionally displayed. By graphing the history of the ranking information or the amount of power and showing the graphed history to the user, it is possible to excite the user to desire aiming at a highly ranked group.

Subsequently, the community tool provision unit 55 determines whether the power saving information is written from the client apparatus 11, which is operated by the user, to the community provided by the server apparatus 12 in step S51. When it is determined that the power saving information is not written in step S51, a process in subsequent step S52 is skipped.

Meanwhile, When it is determined that the power saving information is written in step S51, the process proceeds to step S52, and the community tool provision unit 55 gives points to the household of the user who wrote the power saving information. The database of the points stored in the storage unit 56 is updated by giving new points. According to such a mechanism, the user actively provides information which is helpful to save power, so that it is possible to accelerate the power saving behavior of the whole group (community).

Meanwhile, points may be given when the written power saving information is evaluated as information which is useful to another user, instead, points are given when merely the power saving information is written.

For example, setting is made such that evaluation, such as “It is helpful” or the like, can be input with respect to information written in a bulletin board, and the community tool provision unit 55 gives points when evaluation, such as “It is helpful” or the like, is obtained from another user.

In addition, points may be given by introducing, for example, mechanism, such as the “good” button of a blog or Facebook, or “follow” or the like of Twitter or the like. That is, when another user evaluates the written power saving information as useful information, it may be considered that another user presses the “good” button or “follows”. When the number of pressed “good” buttons or “follows” is equal to or greater than a predetermined number, it is evaluated that useful information is provided, so that points can be given. A user who obtains a large number of “good” or “follows” is equal to “a person who provides superior know-how” in evaluation. Therefore, by giving points based on the number of “good”, “follow” or the like, it is possible to arouse a desire of “providing superior know-how and having more followers”.

The continuation of the effort for sharing the power saving know-how and economizing power can be realized in such a way that the community tool provision unit 55 provides an information sharing system for the above-described power saving information and a point system for power saving information in the communities.

After the process in step S52 is performed or when it is determined that there is no access to the community in step S49, the process returns to step S41 and the processes subsequent to step S41 are repeated.

In the server apparatus 12, the above-described processes are performed.

As described above, the data acquisition unit 51 of the server apparatus 12 obtains power profiles as data indicative of the amount of power consumption consumed by one or more electrical appliances 20 used by a user in each of the households. Thereafter, the group classification unit 53 classifies the households into a predetermined number of groups (communities) based on the obtained power profiles of each of the households.

In addition, the community tool provision unit 55 provides a service for exchanging information about the amount of power consumption by the users of households which belong to a corresponding group. Therefore, it is possible to improve the motivation of the power saving behavior of the users, and it is possible to provide mechanism which enables the users to actively participate in reduction in the amount of power consumption.

### [Example of Calculation for Obtaining Power Profile of Each User]

Meanwhile, as described above, an example in which rank is determined or points are given in units of a household has been described in the present embodiment. However, competition for power saving may be performed between users by determining rank or giving points in units of a user who resides in the household. In this case, it is preferable that the power profiles be aggregated in units of a user. Here, an example of a method of obtaining a power profile for each user based on the power profile of each of the electrical appliances 20 in the household will be described below.

For example, the calculation of the amount of the use of an electrical appliance k (k=1 to K) used by each member (i=1 to I) of a family of I people in a certain household (house) will be described. The family member i includes a father, a mother, a child, or the like, and the family member is simply called a person i, an individual i, or the like below. In addition, it is assumed that there are j (J>2) rooms in the house, and the family member i is present in any one of the rooms 1 to J unless he or she goes out.

The power profile collection unit 41 obtains the power consumption Wₖ(t) of an electrical appliance k in the household at the time t as a power profile, and then stores the obtained power consumption Wₖ(t) in the storage unit 43. Meanwhile, one of the K electrical appliances can be used as a residual background obtained by collecting the power consumption of the whole plurality of electrical appliances in which it is difficult to measure the power consumption of a stand-alone electrical appliance because the power consumption thereof is extremely low.

The user profile classification unit 42 calculates the amount of power consumption Wᵢ of the individual i by allocating total power consumption ΣWₖ(t) in the household for respective individuals i in the household during a predetermined period T (t=1 to T), using Equation (3).

$${W}_{i} = {\sum }_{t}^{ } {\sum }_{j}^{ } {\sum }_{k}^{ } {R}_{ij} ( t ) {E}_{jk} ( t ) {w}_{k} ( t ) \qquad ( 3 )$$

where Rᵢⱼ(t) in Equation (3) indicates the rate of responsibility assignment, which is the rate of power consumed in the room j is shared by people i as the responsibility of everyone in the household at the time t, and Eⱼₖ(t) indicates an equipment existence probability which is a probability that the electrical appliance k (k=1 to K) is present in the room j at the time t. The total sum of the equipment existence probability Eⱼₖ(t) of the entire rooms 1 to J at the time t is 1, and the total sum of the rate of responsibility assignment Rᵢⱼ(t) of all the family members at the time t is also 1.

Therefore, the amount of power consumption Wᵢ of the individual i is obtained by integrating the power consumption Wₖ(t) of the electrical appliance k of the individual i during a predetermined period T, the equipment existence probability Eⱼₖ(t), and the rate of responsibility assignment Rᵢⱼ(t) of the room j of the equipment existence probability Eⱼₖ(t) with respect to the whole electrical appliances and the rooms. In addition, the amount of power consumption Wᵢ of the individual i of a predetermined electrical appliance k can be obtained by performing the summation (Σ) of the whole electrical appliances 1 to K in Equation (3) on only the predetermined electrical appliance k. Therefore, it is possible to calculate the amount of power consumption Wᵢ of the electrical appliance k of the individual i.

As understood from Equation (3), when the amount of power consumption Wᵢ of the individual i is obtained, the rate of responsibility assignment Rᵢⱼ (t) of the individual i in the room j, which indicates the relationship between the individual i and the room (place) j, and the equipment existence probability Eⱼₖ(t) of the electrical appliance k in the room j, which indicates the relationship between the electrical appliance k and the room (place) j, are used. That is, the amount of power consumption Wᵢ of the individual i is obtained without using information indicative of the relationship between an individual and an electrical appliance. As described above, according to Equation (3), even when it is difficult to obtain information indicative of the relationship between an individual and an electrical appliance, it is possible to obtain the amount of power consumption Wᵢ of the individual i by introducing the parameter of a place.

Meanwhile, the predetermined period T may be a range in which commencement and termination is clearly determined, such as a day or a month, and may be a time period which is transferred according to the current time, such as immediate (back from the current time) 24 hours or 30 days.

### [Calculation Method of Amount of Power Consumption Wᵢ of Individual i]

Although the amount of power consumption Wᵢ of the individual i is obtained using Equation (3) as described above, any one of first and second calculation methods can be used as an actual calculation method of Equation (3) based on two concepts below.

### (First Calculation Method)

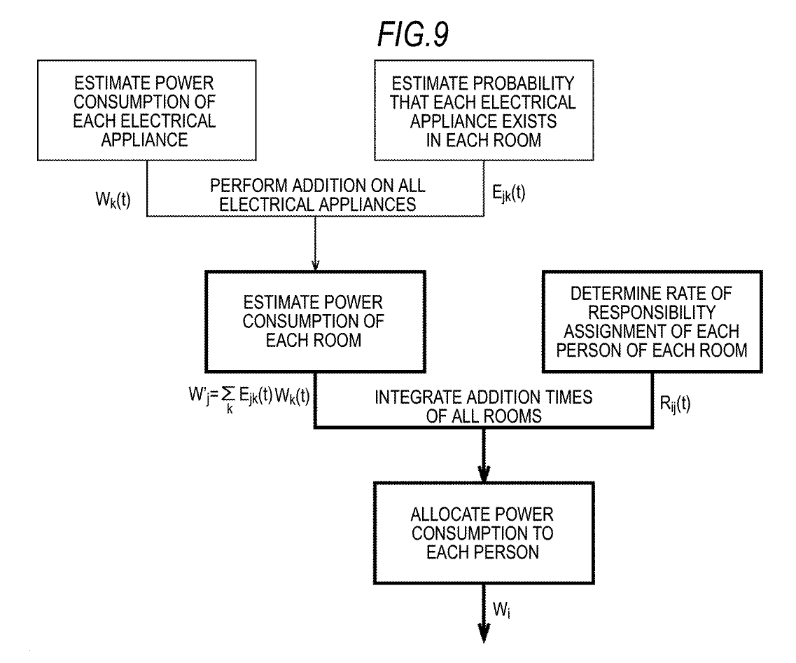

FIG. 9 is a conceptual diagram illustrating a first calculation method of obtaining the amount of power consumption Wᵢ of the individual i.

The first calculation method is a method of performing calculation by decomposing the amount of power consumption ΣWₖ(t) of the whole electrical appliances into units of a room j and allocating power consumption W′ⱼ in units of a room j to each of the individuals i.

That is, a value, obtained by multiplying the power consumption Wₖ(t) of each electrical appliance k by the equipment existence probability Eⱼₖ(t) of each of the electrical appliances k of each of the rooms j, is added to the whole electrical appliances 1 to K, so that the power consumption W′ⱼ for each room j is calculated. In addition, the rate of responsibility assignment Rᵢⱼ(t) of each individual corresponding to each room j is determined. Thereafter, the amount of power consumption corresponding to the rate of responsibility assignment Rᵢⱼ(t) of the person i is obtained from among the power consumption W′ⱼ for each room j, and the obtained power consumption is integrated for the whole rooms, so that the amount of power consumption Wᵢ of the individual is obtained.

When Equation (3) is modified in conformity with first calculation method, the modified Equation can be expressed as the following Equation (4).

$$\begin{matrix}{W}_{i} = {\sum }_{t}^{ } {\sum }_{j}^{ } {W}_{j}^{′} \times {R}_{ij} ( t ) \\ = {\sum }_{t}^{ } {\sum }_{j}^{ } {\sum }_{k}^{ } {E}_{jk} ( t ) {w}_{k} ( t ) {R}_{ij} ( t )\end{matrix} \qquad ( 4 )$$

### (Second Calculation Method)

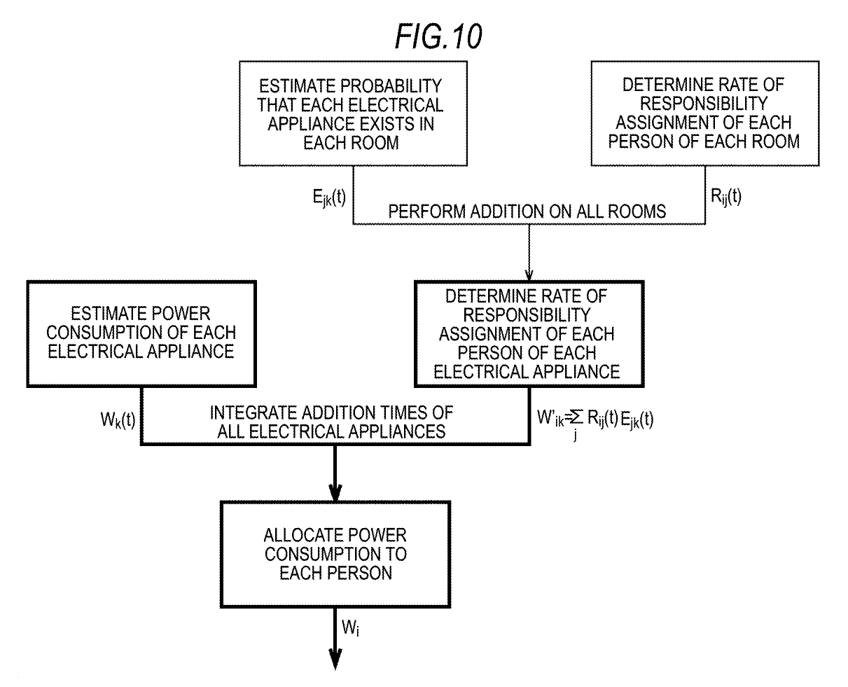

Subsequently, a second calculation method used to obtain the amount of power consumption Wᵢ of the individual i will be described. FIG. 10 is a conceptual diagram illustrating the second calculation method.

The second calculation method is a method of performing calculation by allocating power consumption Wₖ(t) in units of an electrical appliance k to each of the individuals i. The power consumption Wₖ(t) in units of an electrical appliance k can be obtained by the power profile collection unit 41.

First, the rate of responsibility assignment W′ᵢₖ of each of the individuals i corresponding to each electrical appliance k is determined. The rate of responsibility assignment W′ᵢₖ of each of the individuals i corresponding to each electrical appliance k can be obtained by adding a result, obtained by multiplying the rate of responsibility assignment Rᵢⱼ(t) of each of the individuals i corresponding to each room j by the equipment existence probability Eⱼₖ(t) of each electrical appliance k of each room j, with respect to the whole rooms 1 to J. Thereafter, the amount of power consumption Wᵢ of the individual i can be obtained by integrating portions corresponding to the rate of responsibility assignment W′ᵢₖ of each person i for the power consumption Wₖ(t) of the electrical appliance k with respect to the whole electrical appliances.

When Equation (3) is modified in conformity with the second calculation method, the modified Equation can be expressed as the following Equation (5).

$$\begin{matrix}{W}_{i} = {\sum }_{t}^{ } {\sum }_{k}^{ } {W}_{ik}^{′} \times {w}_{k} ( t ) \\ = {\sum }_{t}^{ } {\sum }_{k}^{ } {\sum }_{j}^{ } {E}_{jk} ( t ) {R}_{ij} ( t ) {w}_{k} ( t )\end{matrix} \qquad ( 5 )$$

As described above, if, for example, the power profiles of the respective electrical appliances 20 in the household are already known, the power profiles of the respective electrical appliances 20 in the household can be obtained for each user. In addition, if the power profiles of the respective electrical appliances 20 in the household can be obtained for each user, the power profiles can be also obtained for each user.

Meanwhile, as described above, in addition to the competition performed by determining rank or giving points in units of a household or in units of a user, the competition for reduction in the amount of power consumption may be performed between the electrical appliances 20 by using the electrical appliances 20 which are essentially present in each household as comparison targets.

In the above-described embodiment, an example, has been described in which the power profiles of the respective electrical appliances 20 of each household are accumulated in the server apparatus 12, comparison is performed on (the amount of reduction in) the power consumption for each household, and then rank is determined. However, the present disclosure is not limited to households and can be applied to other environments, such as offices, schools, or the like. That is, power profiles can be collected in units of a region, and the above-described rank or community can be formed by assuming the units of households, offices, schools, or the like as a single region (comparison target region).

### [Configuration Example of Hardware of Information Processing Apparatus and Server Apparatus]

A series of processes performed by the above-described client apparatus 11 and the server apparatus 12 can be performed by hardware or software. In the case where the series of processes are performed by software, a program included in the software is installed in a computer. Here, the computer includes a computer with which dedicated hardware is embedded and a computer, for example, a general-purpose personal computer which is capable of executing various types of functions by installing various types of programs.

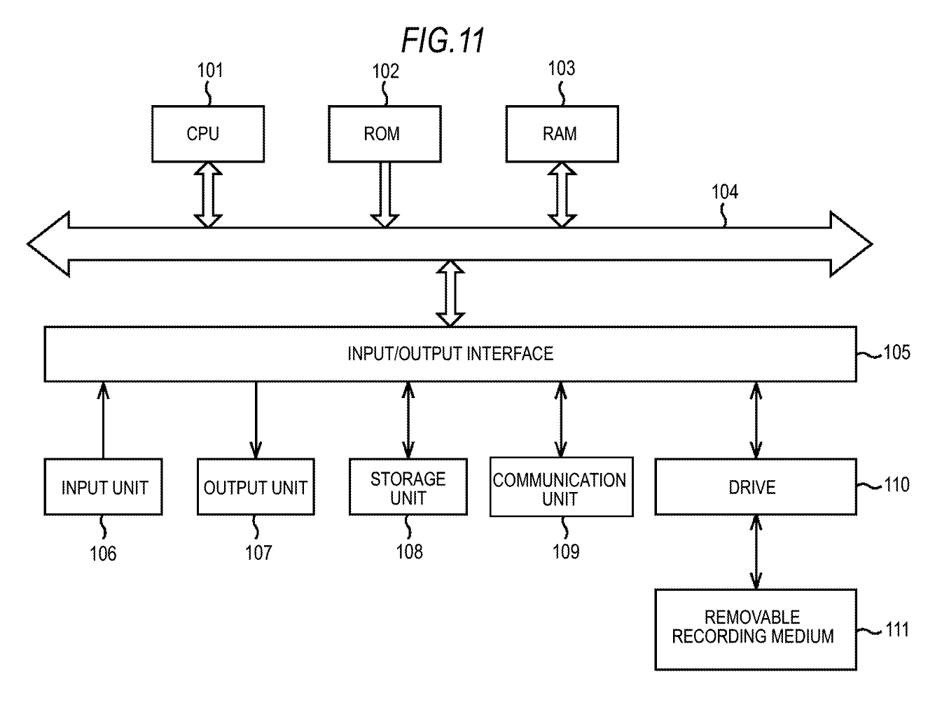

FIG. 11 is a block diagram illustrating a configuration example of the hardware of a computer which functions as the client apparatus 11 or the server apparatus 12, and which performs the above-described series of processes using a program.

In the computer, a CPU (Central Processing Unit) 101, a ROM (Read Only Memory) 102, and a RAM (Random Access Memory) 103 are mutually connected via a bus 104.

In addition, an input/output interface 105 is connected to the bus 104. An input unit 106, an output unit 107, a storage unit 108, a communication unit 109, and a drive 110 are connected to the input/output interface 105.

The input unit 106 includes a keyboard, a mouse, a microphone, or the like. The output unit 107 includes a display, a speaker, or the like. The storage unit 108 includes a hard disk, a nonvolatile memory, or the like. The communication unit 109 includes a network interface or the like. The drive 110 drives a magnetic disc, an optical disc, a magnetic optical disc, or a removable storage medium 111 such as a semiconductor memory or the like.

In the computer configured as described above, the CPU 101 performs the above-described series of processes by loading, for example, a program which is stored in the storage unit 108 onto the RAM 103 via the input/output interface 105 and the bus 104, and then executing the program.

In the computer, the program can be installed in the storage unit 108 via the input/output interface 105 by mounting the removable recording medium 111 on the drive 110. Further, the program can be received using the communication unit 109 via a wired or wireless transmission medium called a local area network, the Internet, or digital satellite broadcasting, and then can be installed in the storage unit 108. In addition, the program can be installed in the ROM 102 or the storage unit 108 in advance.

Meanwhile, in the above-described embodiment, a part of the process, described that the client apparatus 11 performs, may be performed in the side of the server apparatus 12, and a part of the process, described that the server apparatus 12 performs, may be performed in the side of the client apparatus 11. That is, it is possible to appropriately determine one of the client apparatus 11 and the server apparatus 12 which will perform the processes (functions) described in the above-described embodiment based on the throughput capacity of each apparatus, a demand processing speed, or the like.

In the present specification, the steps described in the flowcharts may be performed in time series along the listed order. However, instead of necessarily processing in time series, the steps may be performed in parallel, at the necessary timing where the call is made, or the like.

Meanwhile, in the present specification, the system represents an entire apparatus which includes a plurality of apparatuses.

An embodiment of the present disclosure is not limited to the above-described embodiment, and various modifications are possible without departing from the gist of the present disclosure.

Furthermore, the embodiments of the present technology can be realized as follows.

(1) A computing device, comprising:

at least one processor configured to:
obtain data related to power consumption by at least a first electrical device located in a first region of a plurality of regions; and
classify the first region, based at least in part on the obtained data, into a first group of regions of a plurality of groups of regions.
   (2) The computing device of (1), wherein the first group of regions includes a second region different from the first region, and wherein the at least one processor is further configured to:

provide a service allowing a first user of the first electrical device located in the first region to share information with a second user of a second electrical device located in the second region.

(3) The computing device of (2), wherein the at least one processor is configured to provide the service such that the first user is able to obtain data related to power consumption by one or more electrical devices that are located in the second region and are used by second user.
(4) The computing device of (2), wherein the at least one processor is further configured to:

obtain, for each of the plurality of regions, second data indicative of power consumption by electrical devices located in respective regions; and

classify each of the plurality of regions, based at least in part on the obtained second data, into a respective group of regions in the plurality of groups of regions.

(5) The computing device of (4), wherein the at least one processor is further configured to:

provide the service such that the service allows users of electrical devices located in regions in a same group of regions to share information with one another.

(6) The computing device of (5), wherein the at least one processor is further configured to:

assign a rank to each of one or more regions in the plurality of regions based at least in part on the second data.

(7) The computing device of (6), wherein the at least one processor is configured to provide the service such that the first user is able to obtain a rank of any region in the first group of regions.
(8) The computing device of (1), wherein the data related to power consumption comprises a plurality of values, each value in the plurality of values being indicative of an amount of power consumed by at least the first electrical device at a particular time.
(9) The computing device of (1), wherein the at least one processor is configured to classify the first region at least in part by using a K-means clustering technique or a spectral clustering technique.
(10) The computing device of (1), wherein the at least one processor is configured to perform acts of obtaining and classifying periodically.
(11) The computing device of (1), wherein the first region is a household and the first electrical device is an electrical appliance located in the household.
(12) The computing device of (1), wherein the computing device is located outside of the first region.
(13) A method, comprising:

obtaining data related to power consumption by at least a first electrical device located in a first region of a plurality of regions; and

classifying the first region, based at least in part on the obtained data, into a first group of regions of a plurality of groups of regions.

(14) The method of (13), wherein the first group of regions includes a second region different from the first region, and wherein the method further comprises:

providing a service allowing a first user of the first electrical device located in the first region to share information with a second user of a second electrical device located in the second region.

(15) The method of (14), wherein providing the service comprises providing the service such that the first user is able to obtain data related to power consumption by one or more electrical devices that are located in the second region and are used by second user.
(16) The method of (13), wherein the method further comprises:

obtaining, for each of the plurality of regions, second data indicative of power consumption by electrical devices located in respective regions; and

classifying each of the plurality of regions, based at least in part on the obtained second data, into a respective group of regions in the plurality of groups of regions.

(17) The method of (16), wherein the method further comprises:

providing a service allowing users of electrical devices located in regions in a same group of regions to share information with one another.

(18) The method of (17), further comprising:

assigning a rank to each of one or more regions in the plurality of regions based at least in part on the second data.

(19) The method of (18), wherein the at least one processor is configured to provide the service such that the first user is able to obtain a rank of any region in the first group of regions.
(20) The method of (13), wherein the data related to power consumption comprises a plurality of values, each value in the plurality of values being indicative of an amount of power consumed by at least the first electrical device at a particular time.
(21) The method of (13), wherein classifying the first region comprises using a K-means clustering technique or a spectral clustering technique.
(22) The method of (13), further comprising performing acts of obtaining and classifying periodically.
(23) The method of (13), wherein the first region is a household and the first electrical device is an electrical appliance located in the household.
(24) A computing device, comprising:

at least one processor configured to:
transmit, to at least another computing device, data related to power consumption by at least a first electrical device located in a first region of a plurality of regions; and
receive, from the other computing device, information related to power consumption by at least a second electrical device located in a second region different from the first region,
wherein the first and the second regions are each in a first group of regions of a plurality of groups of regions.
   (25) The computing device of (24), wherein the at least one processor is configured to receive the information related to power consumption by at least the second electrical device by receiving information related to power consumption by an electrical device selected based at least in part on the transmitted data.
   (26) The computing device of (24), wherein the at least one processor is configured to collect, from the first electrical device, the data related to power consumption by the first electrical device.
   (27) The computing device of (24), wherein the computing device is configured to store the data related to power consumption by the first electrical device.
   (28) The computing device of (24), wherein the computing device located inside the first region, and wherein the other computing device is located outside the first region.
   (29) The computing device of (24), wherein the first region is a household and the first electrical device is an electrical appliance located in the household.
   (30) The computing device of (24), wherein the data related to power consumption comprises a plurality of values, each value in the plurality of values being indicative of an amount of power consumed by at least the first electrical device at a particular time.
   (31) A system, comprising:

a first computing device, comprising at least one processor, configured to:
obtain, from a second computing device, data related to power consumption by at least a first electrical device located in a first region of a plurality of regions,
classify the first region, based at least in part on the obtained data, into a first group of regions of a plurality of groups of regions; and

the second computing device, comprising at least another processor, configured to:
transmit, to the first computing device, the data related to power consumption by at least the first electrical device, and
receive, from the first computing device information related to power consumption by a second electrical device located in a second region,
wherein the second region is in the first group of regions.
   (32) The system of (31), wherein the first computing device is configured to:

provide a service allowing a first user of the first electrical device to share information with a second user of a second electrical device located in the second region.

(33) The system of (32), wherein the first computing device is configured to provide the service such that the first user is able to obtain data related to power consumption by one or more electrical devices that are located in the second region and are used by the second user.
(34) The system of (32), wherein the first computing device is further configured to:

obtain, for each of a plurality of regions, second data indicative of power consumption by electrical devices located in respect regions;

classify each of the plurality of regions, based at least in part on the obtained second data, into a respective group of regions in the plurality of groups of regions; and

provide the service such that the service allows for users of electrical devices located in regions in a same group of regions to share information with one another.

(35) The system of (34), wherein the first computing device is further configured to:

provide the service such that the service allows users of electrical devices in regions in a same group or regions to share information with one another.

(36) The system of (34), wherein the first computing device is configured to assign a rank to each of one or more regions in the plurality of regions based at least in part on the second data.
(37) The system of (31), wherein the first computing device is located outside of the first region and the second computing device is located inside the first region.
(38) The system of (31), wherein the second computing device is configured to receive the information related to power consumption by an electrical device, wherein the information is selected, by the first computing device, based at least in part on the transmitted data.
(39) The system of (31), wherein the second computing device is configured to collect, from the first electrical device, the data related to power consumption by the first electrical device.
(40) The system of (31), wherein the first region is a household and the first electrical device is an electrical appliance located in the household.

Some embodiments may comprise a computer-readable storage medium (or multiple computer-readable media) (e.g., a computer memory, one or more floppy discs, compact discs (CD), optical discs, digital video disks (DVD), magnetic tapes, flash memories, circuit configurations in Field Programmable Gate Arrays or other semiconductor devices, or other tangible computer storage media) encoded with one or more programs (e.g., a plurality of processor-executable instructions) that, when executed on one or more computers or other processors, perform methods that implement the various embodiments discussed above. As is apparent from the foregoing examples, a computer-readable storage medium may retain information for a sufficient time to provide computer executable instructions in a non-transitory form. It should be understood by those skilled in the art that various modifications, combinations, sub-combinations and alterations may occur depending on design requirements and other factors insofar as they are within the scope of the appended claims or the equivalents thereof.

Use of ordinal terms such as “first,” “second,” “third,” etc., in the claims to modify a claim element does not by itself connote any priority, precedence, or order of one claim element over another or the temporal order in which acts of a method are performed. Such ordinal terms are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The present disclosure contains subject matter related to that disclosed in Japanese Priority Patent Application JP 2011-181525 filed in the Japan Patent Office on Aug. 23, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A computing device, comprising:
at least one processor configured to:
obtain data related to power consumption by at least a first electrical device located in a first region of a plurality of regions; and
classify the first region, based at least in part on the obtained data, into a first group of regions of a plurality of groups of regions.

2. The computing device of claim 1, wherein the first group of regions includes a second region different from the first region, and wherein the at least one processor is further configured to:
provide a service allowing a first user of the first electrical device located in the first region to share information with a second user of a second electrical device located in the second region.

3. The computing device of claim 2, wherein the at least one processor is configured to provide the service such that the first user is able to obtain data related to power consumption by one or more electrical devices that are located in the second region and are used by second user.

4. The computing device of claim 2, wherein the at least one processor is further configured to:
obtain, for each of the plurality of regions, second data indicative of power consumption by electrical devices located in respective regions; and
classify each of the plurality of regions, based at least in part on the obtained second data, into a respective group of regions in the plurality of groups of regions.

5. The computing device of claim 4, wherein the at least one processor is further configured to:
provide the service such that the service allows users of electrical devices located in regions in a same group of regions to share information with one another.

6. The computing device of claim 5, wherein the at least one processor is further configured to:
assign a rank to each of one or more regions in the plurality of regions based at least in part on the second data.

7. The computing device of claim 6, wherein the at least one processor is configured to provide the service such that the first user is able to obtain a rank of any region in the first group of regions.

8. The computing device of claim 1, wherein the data related to power consumption comprises a plurality of values, each value in the plurality of values being indicative of an amount of power consumed by at least the first electrical device at a particular time.

9. The computing device of claim 1, wherein the at least one processor is configured to classify the first region at least in part by using a K-means clustering technique or a spectral clustering technique.

10. The computing device of claim 1, wherein the at least one processor is configured to perform acts of obtaining and classifying periodically.

11. The computing device of claim 1, wherein the first region is a household and the first electrical device is an electrical appliance located in the household.

12. The computing device of claim 1, wherein the computing device is located outside of the first region.

13. A computing device, comprising:
at least one processor configured to:
transmit, to at least another computing device, data related to power consumption by at least a first electrical device located in a first region of a plurality of regions; and
receive, from the other computing device, information related to power consumption by at least a second electrical device located in a second region different from the first region,
wherein the first and the second regions are each in a first group of regions of a plurality of groups of regions.

14. The computing device of claim 13, wherein the at least one processor is configured to receive the information related to power consumption by at least the second electrical device by receiving information related to power consumption by an electrical device selected based at least in part on the transmitted data.

15. The computing device of claim 13, wherein the at least one processor is configured to collect, from the first electrical device, the data related to power consumption by the first electrical device.

16. The computing device of claim 13, wherein the computing device is configured to store the data related to power consumption by the first electrical device.

17. The computing device of claim 13, wherein the first region is a household and the first electrical device is an electrical appliance located in the household.

18. The computing device of claim 13, wherein the data related to power consumption comprises a plurality of values, each value in the plurality of values being indicative of an amount of power consumed by at least the first electrical device at a particular time.

19. A system, comprising:
a first computing device, comprising at least one processor, configured to:
obtain, from a second computing device, data related to power consumption by at least a first electrical device located in a first region of a plurality of regions,
classify the first region, based at least in part on the obtained data, into a first group of regions of a plurality of groups of regions; and
the second computing device, comprising at least another processor, configured to:
transmit, to the first computing device, the data related to power consumption by at least the first electrical device, and
receive, from the first computing device information related to power consumption by a second electrical device located in a second region,
wherein the second region is in the first group of regions.

20. A method, comprising:
obtaining data related to power consumption by at least a first electrical device located in a first region of a plurality of regions; and
classifying the first region, based at least in part on the obtained data, into a first group of regions of a plurality of groups of regions.
